(19) United States
(12) Patent Application Publication
(10) Pub. No.: US 2015/0168465 A1
(43) Pub. Date: Jun. 18, 2015

(54) METHOD AND APPARATUS FOR ELECTRIC POWER SYSTEM DISTRIBUTION STATE ESTIMATIONS

(71) Applicant: General Electric Company, Schenectady, NY (US)

(72) Inventors: Kasi Viswanadha Raju Gadiraju, Bangalore (IN); Amol Rajaram Kolwalkar, Bangalore (IN); Mallikarjuna R. Vallem, Richland, WA (US)

(73) Assignee: General Electric Company, Schenectady, NY (US)

(21) Appl. No.: 14/105,769

(22) Filed: Dec. 13, 2013

(51) Int. Cl. G01R 21/133; G01R 21/00

(52) U.S. Cl. CPC G01R 21/1331; G01R 21/002; G01R 21/003

(57) ABSTRACT

A method of estimating a state of an electric power distribution system that includes a plurality of nodes and at least one electrical monitoring sensor includes measuring electric current flow (I), real power flow (P), and reactive power flow (Q). The method also includes determining estimated real power load values (P_{Li}s) and reactive power load values (Q_{Li}s) and determining a plurality of estimated load current values (I_{Li}s) based on the P_{Li}s and the Q_{Li}s. The method further includes measuring a value of voltage (V_{M}) for at least one node and determining a voltage estimate (Vᵢ) for the node. The method also includes comparing the Vᵢ with the V_{M}, thereby determining a difference value between the Vᵢ and the V_{M}. The method further includes determining that the difference value exceeds a threshold and adjusting the P_{Li}s and the Q_{Li}s to match the Vᵢ and the V_{M}.

### BACKGROUND

The field of the disclosure relates generally to electric power distribution systems and, more particularly, to distribution state estimation (DSE) systems configured to determine a state of such electric power distribution systems.

Known electric power systems typically include power generation plants, transmission and distribution lines, transformers, and other devices that facilitate electric power transmission, and power delivery. After electric power is generated in the generating plants, it is transmitted for extended distances through the high voltage transmission lines to sub-transmission/distribution substations. Transmission lines usually operate at voltage levels between approximately 115 kilovolts (kV) and approximately 765 kV. At the sub-transmission/distribution substations, transformers reduce the high voltage at which the power has been transmitted to sub-transmission voltage levels that range from approximately 46 kV to approximately 69 kV, or to distribution voltage levels that range from approximately 12 kV to approximately 34.5 kV. Power is then transmitted through a feeder to an end customer through an electric distribution system, and before it reaches the end customer, the voltage is decreased to approximately 120V/240V by a distribution transformer.

Most known electric power distribution systems include a plurality of segments. Each segment includes commercial and/or residential electric power customers that facilitate a dynamic state of the segments, and therefore a dynamic state of the electric distribution system. Also, some of the segments may include distributed generation (DG) devices coupled throughout the segments, thereby increasing the variability of electric power transmission through the electric power distribution system. These electric distribution systems typically use a distribution management system (DMS) in conjunction with a supervisory control and data acquisition (SCADA) systems for monitoring and control of the electric power distribution system.

However, most known electric power distribution systems have limited real-time measurements due to the scarcity of measurement devices. To facilitate the delivery of electric power to the customers with the appropriate quality characteristics, i.e., voltages within tolerance, knowledge of the distribution state of the various segments needs to be known, or estimated with a high degree of confidence in real-time. Placement of voltage sensors throughout most or all of the segments is quite expensive. Therefore, in lieu of hardware solutions, many known DMSs include software solutions, i.e., a distribution state estimation (DSE) system. However, known computational-based methods, e.g., known DSE algorithms using known mathematical methods, e.g., weighted least squares (WLS) methods may be used to generate the state estimations while incorporating the limited measurements available. Such system-generated state estimates have the limitation of being computationally intensive and time consuming, thereby decreasing the value of the state estimation outputs due to the temporal delays and the high variability of the distribution system. As such, incorporating voltage determinations with a high degree of confidence in known DSEs has been a challenge.

### BRIEF DESCRIPTION

In one aspect, a computer-based method of estimating a state of an electric power distribution system using a computer device including at least one processor is provided. The electric power distribution system includes a plurality of nodes and at least one electrical monitoring sensor positioned therein. The method includes measuring at least one of electric current flow (I), real power flow (P), and reactive power flow (Q) and receiving a value of the at least one of I, P, and Q by the computing device. The method also includes determining, by the processor, at least one of at least one estimated real power load value (P_{Li}) and at least one estimated reactive power load value (Q_{Li}). The method further includes determining, by the processor, a plurality of estimated load current values (I_{Li}s) based on the at least one of the at least one P_{Li} and the at least one Q_{Li}. The method also includes measuring a value of voltage (V_{M}) for at least one node within the plurality of nodes and receiving the value of the V_{M} by the computing device. The method further includes determining, by the processor, a voltage estimate (Vᵢ) for the at least one node within the plurality of nodes. The method also includes comparing, by the processor, the Vᵢ with the V_{M}, thereby determining a difference value between the Vᵢ and the V_{M}. The method further includes determining, by the processor, that the difference value exceeds a predetermined threshold. The method also includes adjusting, by the processor, the at least one of the at least one P_{Li} and the at least one Q_{Li} to facilitate substantially equalizing the Vᵢ with the V_{M}.

In a further aspect, a computer-based distribution state estimation (DSE) system for estimating a state of an electric power distribution system is provided. The electric power distribution system includes a plurality of nodes positioned therein. The electric power distribution system further includes an integrated volt/VAR control (IVVC) system. The DSE system includes at least one measurement device and at least one processor coupled to the at least one measurement device. The at least one processor is configured to determine at least one of at least one estimated real power load value (PO and at least one estimated reactive power load value (Q_{Li}). The processor is also configured to determine a plurality of estimated load current values (I_{Li}s) based on the at least one of the at least one P_{Li} and the at least one Q_{Li}. The processor is further configured to determine a voltage estimate (Vᵢ) for at least one node in the plurality of nodes. The processor is also configured to compare the Vᵢ with a measured value of voltage (V_{M}) for the at least one node within the plurality of nodes, thereby determine a difference value between the Vᵢ and the V_{M}. The processor is further configured to determine that the difference value exceeds a predetermined threshold and adjust the at least one of the at least one P_{Li} and the at least one Q_{Li} to facilitate substantially equalizing the Vᵢ with the V_{M}.

In another aspect, one or more computer-readable storage media having computer-executable instructions embodied thereon is provided. When executed by at least one processor, the computer-executable instructions cause the at least one processor to determine at least one of at least one estimated real power load value (Pᵢ) and at least one estimated reactive power load value (Q_{Li}). The computer-executable instructions also cause the at least one processor to determine a plurality of estimated load current values (I_{Li}s) based on the at least one of the at least one P_{Li} and the at least one Q_{Li}. The computer-executable instructions further cause the at least one processor to determine a voltage estimate (Vᵢ) for at least one node in the plurality of nodes. The computer-executable instructions also cause the at least one processor to compare the V, with a measured value of voltage (V_{M}) for the at least one node within the plurality of nodes, thereby determine a difference value between the Vᵢ and the V_{M}. The computer-executable instructions further cause the at least one processor to determine that the difference value exceeds a predetermined threshold and adjust the at least one of the at least one P_{Li} and the at least one Q_{Li} to facilitate substantially equalizing the Vᵢ with the V_{M}.

### DRAWINGS

These and other features, aspects, and advantages of the present invention will become better understood when the following detailed description is read with reference to the accompanying drawings in which like characters represent like parts throughout the drawings, wherein:

FIG. 1 is a block diagram of an exemplary computing device;

FIG. 2 is a block diagram of a portion of an exemplary distribution state estimation (DSE) system that may include the computing device shown in FIG. 1;

FIG. 3 is a schematic diagram of a portion of an exemplary electric power distribution system for which the DSE system shown in FIG. 2 may be used to estimate a state;

FIG. 4 is a schematic process flow chart of the DSE system shown in FIG. 2 used to estimate the state of the electric power distribution system shown in FIG. 3;

FIG. 5 is a flow chart of an exemplary method for determining a distribution state estimation (DSE) of the portion of the electric power distribution system shown in FIG. 3 for which the DSE system shown in FIGS. 2 and 3 and the process in FIG. 4 are used;

FIG. 6 is a continuation of the flow chart shown in FIG. 5;

FIG. 7 is a continuation of the flow chart shown in FIG. 6;

FIG. 8 is a schematic view of a portion of the electric power distribution system shown in FIG. 3 for describing a voltage matching constraint; and

FIG. 9 is an exemplary configuration of a database within the computing device shown in FIG. 1, along with other related computing components, that may be used to determine a DSE as described herein.

Unless otherwise indicated, the drawings provided herein are meant to illustrate features of embodiments of the disclosure. These features are believed to be applicable in a wide variety of systems comprising one or more embodiments of the disclosure. As such, the drawings are not meant to include all conventional features known by those of ordinary skill in the art to be required for the practice of the embodiments disclosed herein.

### DETAILED DESCRIPTION

In the following specification and the claims, reference will be made to a number of terms, which shall be defined to have the following meanings.

The singular forms “a”, “an”, and “the” include plural references unless the context clearly dictates otherwise.

“Optional” or “optionally” means that the subsequently described event or circumstance may or may not occur, and that the description includes instances where the event occurs and instances where it does not.

Approximating language, as used herein throughout the specification and claims, may be applied to modify any quantitative representation that could permissibly vary without resulting in a change in the basic function to which it is related. Accordingly, a value modified by a term or terms, such as “about” and “substantially”, are not to be limited to the precise value specified. In at least some instances, the approximating language may correspond to the precision of an instrument for measuring the value. Here and throughout the specification and claims, range limitations may be combined and/or interchanged, such ranges are identified and include all the sub-ranges contained therein unless context or language indicates otherwise.

As used herein, the term “computer” and related terms, e.g., “computing device”, are not limited to integrated circuits referred to in the art as a computer, but broadly refers to a microcontroller, a microcomputer, a programmable logic controller (PLC), an application specific integrated circuit, and other programmable circuits, and these terms are used interchangeably herein.

Further, as used herein, the terms “software” and “firmware” are interchangeable, and include any computer program stored in memory for execution by personal computers, workstations, clients and servers.

As used herein, the term “non-transitory computer-readable media” is intended to be representative of any tangible computer-based device implemented in any method or technology for short-term and long-term storage of information, such as, computer-readable instructions, data structures, program modules and sub-modules, or other data in any device. Therefore, the methods described herein may be encoded as executable instructions embodied in a tangible, non-transitory, computer readable medium, including, without limitation, a storage device and/or a memory device. Such instructions, when executed by a processor, cause the processor to perform at least a portion of the methods described herein. Moreover, as used herein, the term “non-transitory computer-readable media” includes all tangible, computer-readable media, including, without limitation, non-transitory computer storage devices, including, without limitation, volatile and nonvolatile media, and removable and non-removable media such as a firmware, physical and virtual storage, CD-ROMs, DVDs, and any other digital source such as a network or the Internet, as well as yet to be developed digital means, with the sole exception being a transitory, propagating signal.

Furthermore, as used herein, the term “real-time” refers to at least one of the time of occurrence of the associated events, the time of measurement and collection of predetermined data, the time to process the data, and the time of a system response to the events and the environment. In the embodiments described herein, these activities and events occur substantially instantaneously.

In addition, as used herein, the term “state estimation” refers to a method and/or process for computing unknown state vectors of a dynamic system by combining sensor measurements with calculated determined predictions and/or estimations from a process model. Therefore, as used herein, the term “distribution state estimation” refers to determining state estimations for electric power distribution systems. More particularly, the state estimations described herein refer to estimating voltage magnitudes and phase angles at a plurality of buses throughout at least a portion of an electric power distribution system.

The distribution state estimation (DSE) system for the electric power distribution systems described herein provide a cost-effective method for facilitating the quality of voltage on segments of the distribution systems that do not have hardware monitoring devices for real-time voltage measurements. Specifically, the embodiments described herein extend the functionality of known DSEs to estimate voltages throughout the distribution system with a significant improvement in accuracy in real-time. More specifically, the embodiments described herein extend the functionality of known DSEs from merely converging with respect to current flows throughout the distribution system to converging with respect to node voltages. The resultant high-confidence estimated voltage values facilitate operation of voltage control applications such as, without limitation, integrated volt/VAR control (IVVC), coordinated volt/VAR control (CVVC), and conservation voltage reduction (CVR).

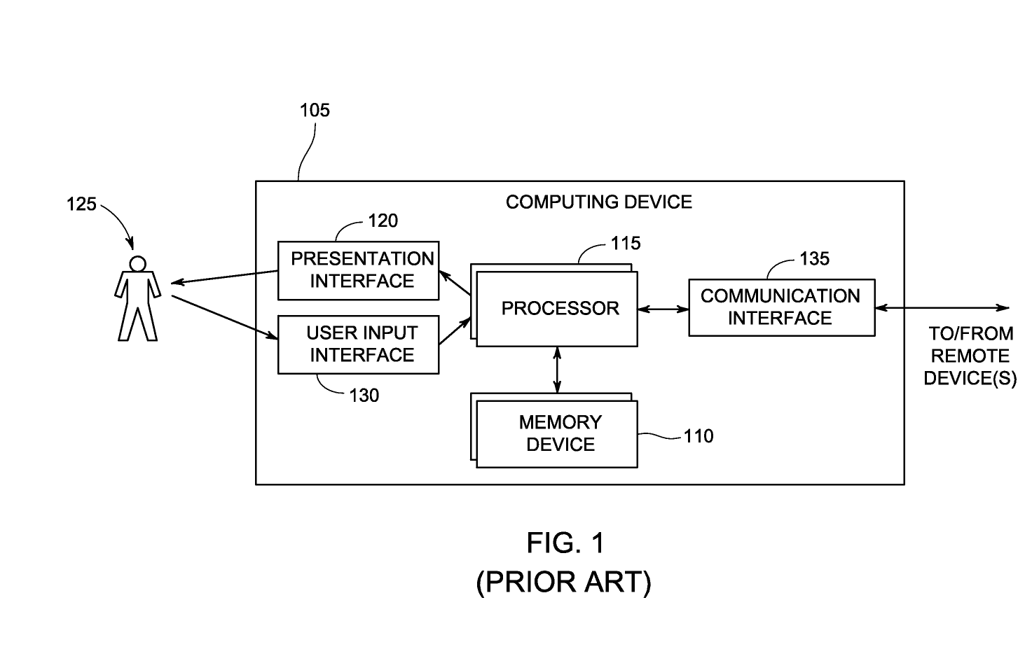

FIG. 1 is a block diagram of an exemplary computing device 105 that may be used to estimate the state of an electric power distribution system (not shown in FIG. 1) through a distribution state estimation (DSE) system (not shown in FIG. 1) at least partially resident within computing device 105. More specifically, computing device 105 generates estimations of currents and voltages throughout the electric power distribution system. Computing device 105 includes a memory device 110 and a processor 115 operatively coupled to memory device 110 for executing instructions. In some embodiments, executable instructions are stored in memory device 110. Computing device 105 is configurable to perform one or more operations described herein by programming processor 115. For example, processor 115 may be programmed by encoding an operation as one or more executable instructions and providing the executable instructions in memory device 110. In the exemplary embodiment, memory device 110 is one or more devices that enable storage and retrieval of information such as executable instructions and/or other data. Memory device 110 may include one or more computer readable media.

Memory device 110 may be configured to store operational measurements including, without limitation, real-time and historical voltage and current values, and/or any other type data. Also, memory device 110 includes, without limitation, sufficient data, algorithms, and commands to facilitate generating estimations of currents and voltages throughout the electric power distribution system.

In some embodiments, computing device 105 also includes sufficient computer-readable/executable instructions, data structures, program modules, and program sub-modules, to receive resultant high-confidence estimated voltage values from the DSE systems described herein to facilitate operation of voltage control applications such as, without limitation, integrated volt/VAR control (IVVC), coordinated volt/VAR control (CVVC), and conservation voltage reduction (CVR).

In some embodiments, computing device 105 includes a presentation interface 120 coupled to processor 115. Presentation interface 120 presents information, such as a user interface and/or an alarm, to a user 125. In some embodiments, presentation interface 120 includes one or more display devices. In some embodiments, presentation interface 120 presents an alarm associated with the electric power distribution system being evaluated, such as by using a human machine interface (HMI) (not shown in FIG. 1). Also, in some embodiments, computing device 105 includes a user input interface 130. In the exemplary embodiment, user input interface 130 is coupled to processor 115 and receives input from user 125.

A communication interface 135 is coupled to processor 115 and is configured to be coupled in communication with one or more other devices, such as a sensor or another computing device 105, and to perform input and output operations with respect to such devices while performing as an input channel. Communication interface 135 may receive data from and/or transmit data to one or more remote devices. For example, a communication interface 135 of one computing device 105 may transmit an alarm to the communication interface 135 of another computing device 105. In some embodiments, communication interface 135 is a wireless interface.

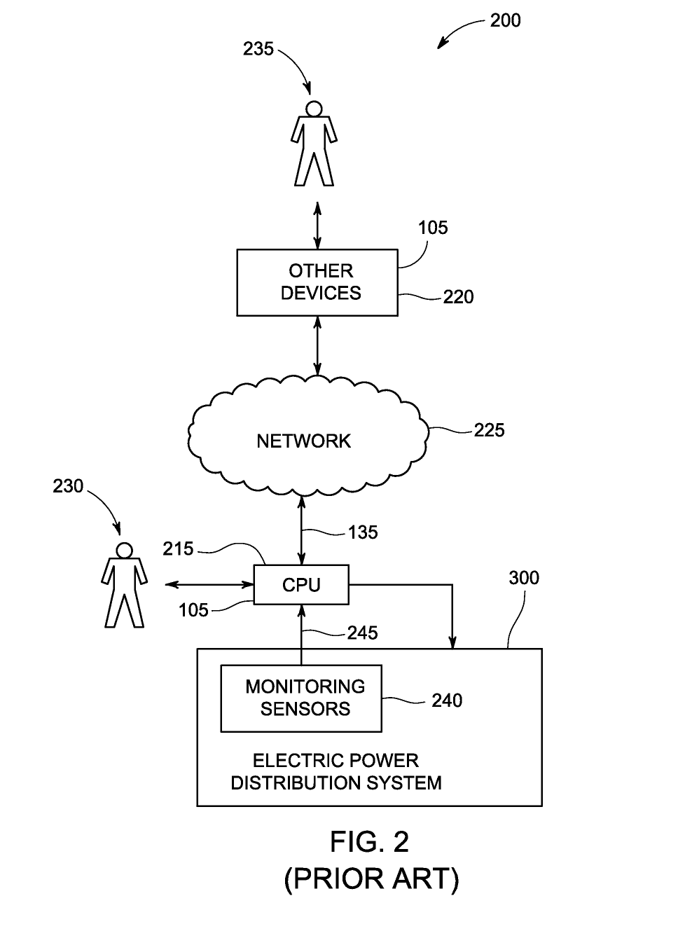

FIG. 2 is a block diagram of a portion of a distribution management system (DMS), i.e., in the exemplary embodiment, a distribution state estimation (DSE) system 200 that may be used to monitor and control at least a portion of an electric power distribution system 300. In some embodiments, the DMS also includes sufficient computer-readable/executable instructions, data structures, program modules, and program sub-modules, to receive resultant high-confidence estimated voltage values from DSE system 200 described herein to facilitate operation of voltage control applications such as, without limitation, IWC systems, CVVC systems, and CVR systems. Alternatively, DSE system 200 is a stand-alone system. Further, alternatively, DSE system 200 is any computer-based system that may monitor portions of, and generate voltage, current, and load estimations for, portions of electric power distribution system 300. In the exemplary embodiment, DSE system 200 includes at least one central processing unit (CPU) 215 configured to execute monitoring algorithms and monitoring logic. CPU 215 may be coupled to other devices 220 via a network 225. In some embodiments, network 225 is a wireless network.

Referring to FIGS. 1 and 2, CPU 215 is a computing device 105. In the exemplary embodiment, computing device 105 is coupled to network 225 via communication interface 135. In an alternative embodiment, CPU 215 is integrated with other devices 220.

CPU 215 interacts with a first operator 230, e.g., without limitation, via user input interface 130 and/or presentation interface 120. In one embodiment, CPU 215 presents information about electric power distribution system 300, such as measured and estimated voltages and currents, to operator 230. Other devices 220 interact with a second operator 235, e.g., without limitation, via user input interface 130 and/or presentation interface 120. For example, other devices 220 present alarms and/or other operational information to second operator 235. As used herein, the term “operator” includes any person in any capacity associated with operating and maintaining electric power distribution system 300, including, without limitation, shift operations personnel, maintenance technicians, and facility supervisors.

In the exemplary embodiment, electric power distribution system 300 includes one or more monitoring sensors 240 coupled to CPU 215 through at least one input channel 245. Monitoring sensors 240 collect operational measurements including, without limitation, alternating current (AC) electric power flow such as, without limitation, current, real power, and reactive power transmitted through portions of electric power distribution system 300. Monitoring sensors 240 also collect operational measurements including, without limitation, AC voltages in portions of electric power distribution system 300. Monitoring sensors 240 repeatedly, e.g., periodically, continuously, and/or upon request, transmit operational measurement readings at the time of measurement. CPU 215 receives and processes the operational measurement readings. Such data is transmitted across network 225 and may be accessed by any device capable of accessing network 225 including, without limitation, desktop computers, laptop computers, and personal digital assistants (PDAs) (neither shown).

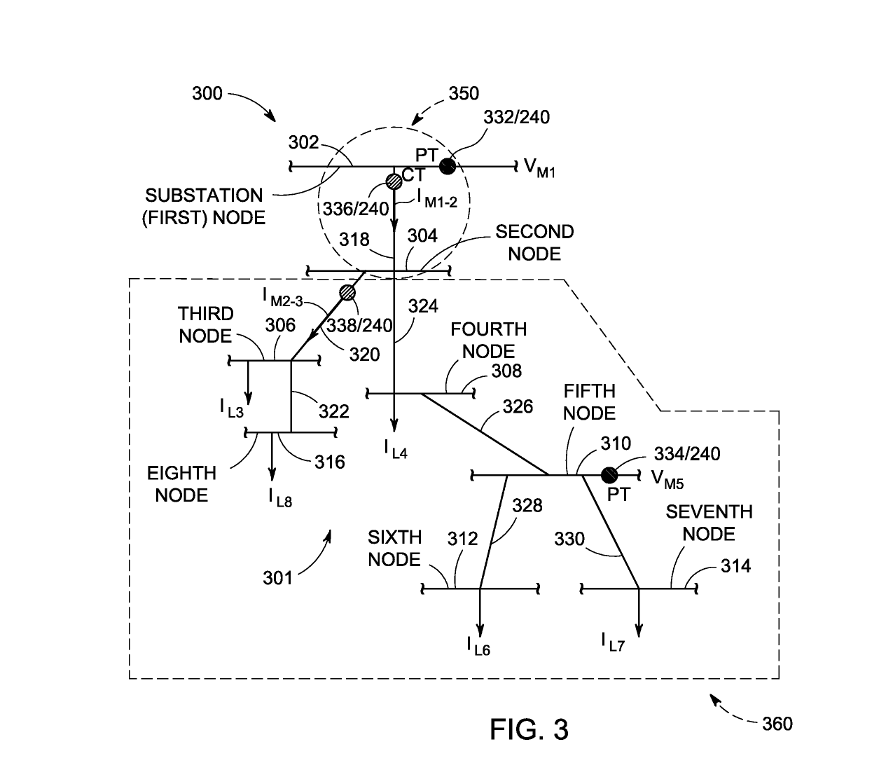

FIG. 3 is a schematic diagram of a portion 301 of an exemplary electric power distribution system 300 for which DSE system 200 (shown in FIG. 2) may be used to estimate a state of electric power distribution system 300. In the exemplary embodiment, portion 301 includes a first node, i.e., substation node 302. Also, portion 301 includes a second node 304, a third node 306, a fourth node 308, a fifth node 310, a sixth node 312, a seventh node 314, and an eighth node 316. Substation node 302 is coupled to second node 304 through a segment 318. Second node 304 is coupled to third node 306 through a segment 320. Third node 306 is coupled to eighth node 316 through a segment 322. Second node 304 is coupled to fourth node 308 through a segment 324. Fourth node 308 is coupled to fifth node 310 through a segment 326. Fifth node 310 is coupled to sixth node 312 through a segment 328. Also, fifth node 310 is coupled to seventh node 314 through a segment 330. As used herein, the term “node” refers to at least a portion of a bus. Segments are sometimes referred to as branches.

In some embodiments, electric power distribution system 300 includes one or more of voltage control applications such as, without limitation, IVVC systems, CVVC systems, and CVR systems. Also, in some embodiments, electric power distribution system 300 includes one or more computing devices similar to computing device 105 (shown in FIGS. 1 and 2) that include sufficient computer-readable/executable instructions, data structures, program modules, and program sub-modules, to facilitate operation of voltage control applications such as, without limitation, IVVC systems, CVVC systems, and CVR systems. More specifically, in such embodiments, electric power distribution system 300 includes one or more computing devices similar to computing device 105 that receive resultant high-confidence estimated voltage values from DSE system 200 as described herein to facilitate operation of voltage control applications such as, without limitation, integrated volt/VAR control (IVVC), coordinated volt/VAR control (CVVC), and conservation voltage reduction (CVR). Further, in those embodiments that have, for example, and without limitation, an IVVC system, electric power distribution system 300 also includes volt-var control devices operatively coupled to the IVVC system, such as, and without limitation, capacitor banks, on-load tap changers (OLTCs), and distributed generators (DGs).

Also, in the exemplary embodiment, portion 301 of electric power distribution system 300 includes monitoring sensors 240. Specifically, a first potential transformer (PT) 332 is coupled to substation node 302 to transmit signals representative of a voltage potential V_{M1} of substation node 302 to CPU 215 (shown in FIG. 2) of DSE system 200. Similarly, a second PT 334 is coupled to fifth node 310 to transmit signals representative of a voltage potential V_{M5} of fifth node 310 to CPU 215. Portion 301 further includes a first current transformer (CT) 336 coupled to segment 318 to transmit signals representative of a measured electric current I_{M1-2} to CPU 215. In addition, portion 301 includes a second CT 338 coupled to segment 320 to transmit signals representative of a measured electric current I_{M2-3} to CPU 215. Therefore, PTs 332 and 334 and CTs 336 and 338 are substantially the totality of monitoring sensors 240 in portion 301. The remainder of the indications of portion 301 are derived.

In some embodiments, a determined real power flow P_{D} and a determined reactive power flow Q_{D} are derived from the real-time voltage measurements (V_{M}) and real-time current measurements (I_{M}). In addition, in some embodiments, in contrast to direct measurements of current flows I_{M}s through installed current transducers, measured currents I_{M}s are also derived from real power flow measurement (P_{M}) devices and reactive power flow measurement (Q_{M}) devices.

Also, in the exemplary embodiment, portion 301 of electric power distribution system 300 is further shown as a first plurality of nodes 350 and a second plurality of nodes 360. First plurality of nodes 350 includes nodes 302 and 304, PT 332, CT 336, and segment 318. Second plurality of nodes 360 includes the balance of the devices shown in FIG. 3 included within portion 301 and positioned downstream of first plurality of nodes 350, e.g., PT 334 and CT 338. As such, first plurality of nodes 350 and second plurality of nodes 360 as shown in FIG. 3 are selected to illustrate the concepts disclosed herein with simple graphics. Alternatively, first plurality of nodes 350 and second plurality of nodes 360 may be configured in any manner that enables operation of system 300 as described herein, including, distributed, non-contingent pluralities of nodes, and more than two pluralities of nodes, grouped as a function of predetermined criteria.

Also, in some alternative embodiments, additional and/or alternative instrumentation may be used throughout portion 301 of electric power distribution system 300 to measure line electricity flow, i.e., electric current, real power, reactive power. First plurality of nodes 350 and second plurality of nodes 360 may include one or more pieces of instrumentation to measure line electricity flow. For example, and without limitation, in some embodiments, in contrast to direct measurements of current flows I_{M}s through installed current transducers, measured currents I_{M}s are derived from real power flow measurement (P_{M}) devices and reactive power flow measurement (Q_{M}) devices.

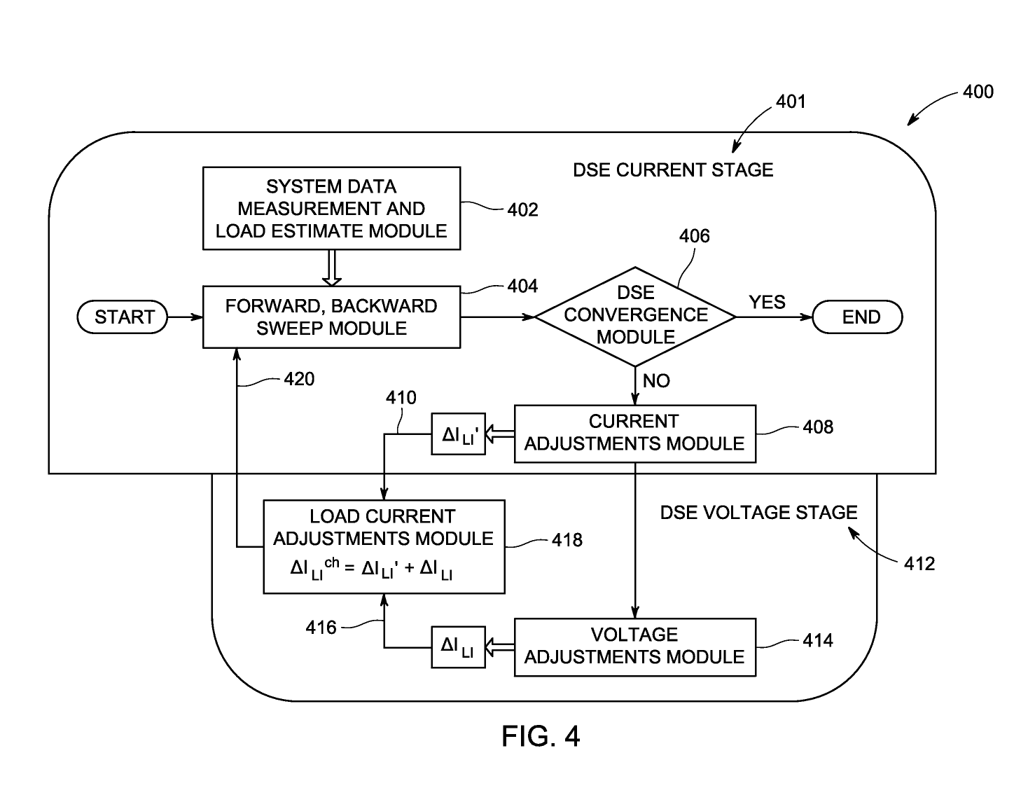

FIG. 4 is a schematic, high level, modular process flow chart 400 of DSE system 200 used to estimate the state of portion 301 of electric power distribution system 300 (both shown in FIG. 3).

In the exemplary embodiment, process flow chart 400 includes a DSE current stage 401. DSE stage 401 includes a system data measurement and load estimate module 402 that includes system data collection including, without limitation, system measurement collection and load estimate generation. Load estimate module 402 is also programmed with the details of the system topology of electric power distribution system 300. DSE stage 401 also includes a forward and backward sweep module 404 that executes at least one forward and backward sweep of the data collected and generated in module 402. As used herein, the term “forward sweep” refers to determining estimated values starting at an upstream point and continuing to a predetermined point downstream. Also, as used herein, the term “backward sweep” refers to determining estimated values starting at a predetermined downstream point and continuing up to a predetermined upstream point.

DSE stage 401 further includes a DSE convergence module 406 that makes a determination if the DSE is sufficiently converged. DSE stage 401 also includes a current adjustments module 408 that generates a ΔI_{Li}′ signal 410 that represents load current adjustments at the i^{th} node to substantially equalize with, or match one or more of current measurements, real power flow measurements, and reactive power flow measurements that are immediately upstream. As such, the load current adjustments are constrained within the parameters defined by Kirchoff s Current Law (KCL) as described by the equation:

$${\sum }_{k = 1}^{n} {I}_{k} = 0 , \qquad ( 1 )$$

where k represents a particular segment, n represents the total number of segments that define a junction at the i^{th} node, Iₖ represents the current transmitted from the k^{th} segment into the i^{th} node, and the summation of all of the currents in the n segments transmitted towards and away from the i^{th} node is zero.

Process flow chart 400 also includes a DSE voltage stage 412. DSE voltage stage 412 includes a voltage adjustments module 414 that generates a ΔI_{Li} signal 416 that represents additional load current adjustments at the i^{th} node to substantially equalize with, or match voltage measurements within the parameters defined by KCL as described by equation (1). Similarly, Kirchoff s Voltage Law (KVL) is adhered to as described by the equation:

$${V}_{M 1} - {V}_{4} - {\sum }_{z = 1}^{m} {V}_{z} = 0 , \qquad ( 2 )$$

where z represents a particular segment, m represents the total number of segments that define a loop, for example, segments 318 and 324 between first node 302 and fourth node 308, V_{z} represents the voltage drop along the z^{th} segment, and the summation of all of the voltages along the loop defined by the m segments is zero.

DSE voltage stage 412 also includes a load current adjustments module 418 that receives signals 410 and 416 representative of ΔI_{Li}′ and AU respectively, and generates a ΔI_{Li}^{ch} signal 420 representative of the total load current adjustments to match current, real and reactive power flow, and voltage measurements with respective estimates at the i^{th} node as described by the equation:

ΔI_{Li}^{ch}=ΔI_{Li}′+ΔI_{Li}. (3)

Signal 420 is transmitted to forward and backward sweep module 404 to facilitate an iterative cycle of estimated current adjustments until both current estimations and voltage estimations throughout portion 301 converge as described further below.

In portion 301 of electric power distribution system 300, not all of segments 318 through 330 have installed instrumentation. Therefore, currents and voltages in those nodes and segments of portion 301 need to be estimated. As such, process flow chart 400 facilitates generating real power load estimates and reactive power load estimates in predetermined regions of portion 301 generated from measured and estimated current and voltage values associated with portion 301. The KCL and KVL equations (1) and (2), respectively, above are both adhered to as revised estimations of voltages and currents are generated. In some embodiments, the voltage measurements and estimations include both magnitudes and phase angles. In some other embodiments, the voltage measurements and estimations include only one of magnitudes and phase angles.

Specifically, DSE current stage 401 uses real power load estimates and reactive power load estimates, generated iteratively, in predetermined regions of portion 301, using measured and estimated current and voltage values associated with portion 301. These iteratively revised estimations of real and reactive power loads are used to iteratively generate revised estimates of current transmission in each of the segments in portion 301 adhering to KCL equation (1). In general, the estimated currents associated with downstream segments and nodes are revised to more closely conform to immediately upstream nodes and segments.

In addition, DSE voltage stage 412 uses the iteratively determined real power load estimates and reactive power load estimates described above in portion 301 to generate revised estimates of current in each of the segments in portion 301 adhering to KCL equation (1) and KVL equation (2). More specifically, changes in the iteratively determined real power load estimates and reactive power load estimates determine corresponding changes in the associated current flows. The revised current estimates are used to generate revised voltage estimates throughout portion 301, thereby generating an accurate estimate of the distribution state of portion 301.

Therefore, the revised estimations of current derived from the determined real and reactive power loads in every iteration is performed using the latest estimates of voltages in portion 301. Both voltage and current estimates are matched with respective measurements and/or derivations in every iteration, until the estimated current values and voltage values converge. In the exemplary embodiment of process 400, DSE convergence is considered to be achieved when a voltage difference between two successive iterations at all nodes 302 through 316 is determined to be less than 0.01 percent, i.e., 0.0001, or 1*10⁻⁴ of a predetermined base value. For example, and without limitation, if the first of two estimations of voltage is 110 volts, and if the second voltage estimate is between 109.9999 volts and 110.0001 volts, voltage for that particular node is considered converged. Alternatively, any value to define convergence may be used that enables operation of process 400 as described herein. Also, alternatively, any other convergence criteria that enables operation of process 400 as described herein may also be used.

Load current adjustments to match voltage measurements and estimations are evaluated as discussed further below to iteratively reduce the changes in load current estimations after satisfying KCL equation (1). As the iterations progress, these load current adjustments will tend to decline and approach zero. In general, current and voltage estimations are not used to overwrite real-time voltage and current measurements generated through monitoring sensors 240.

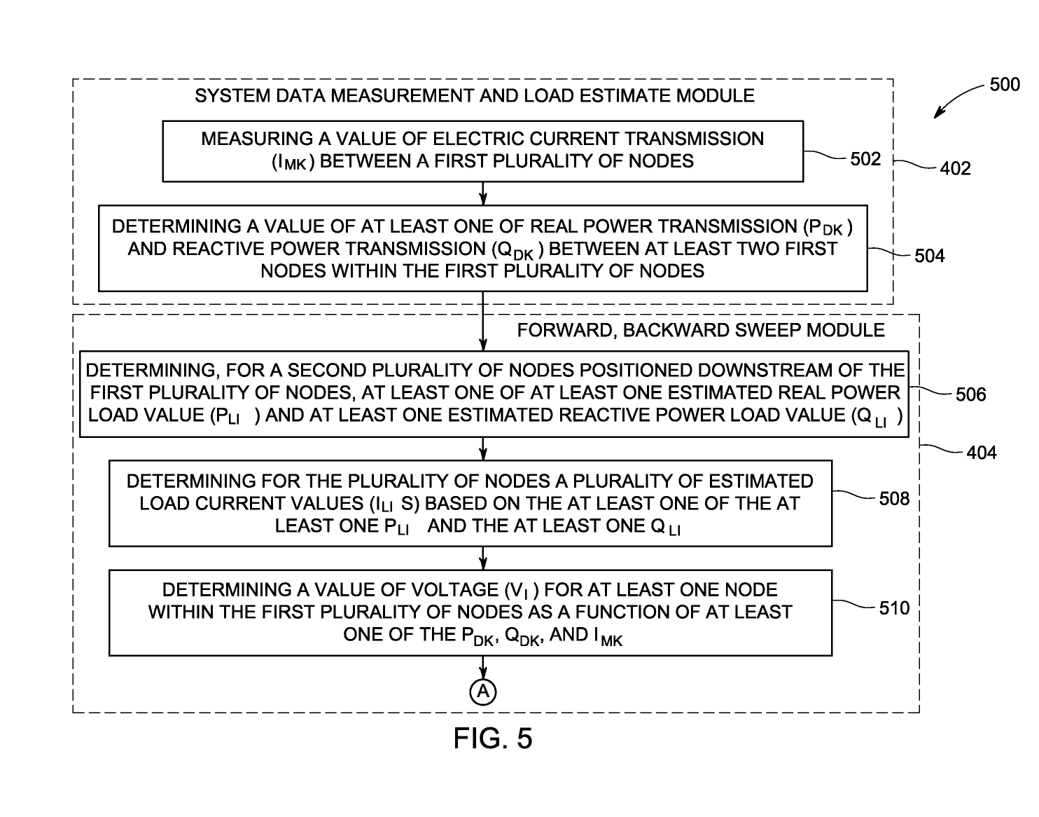

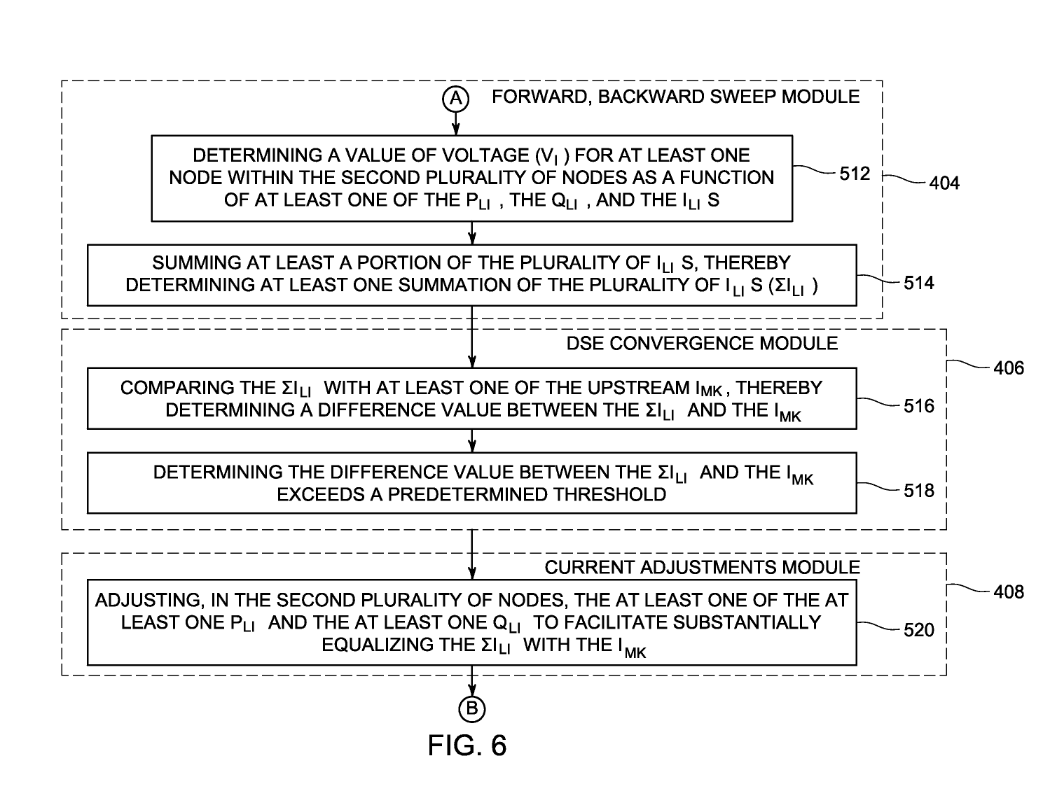

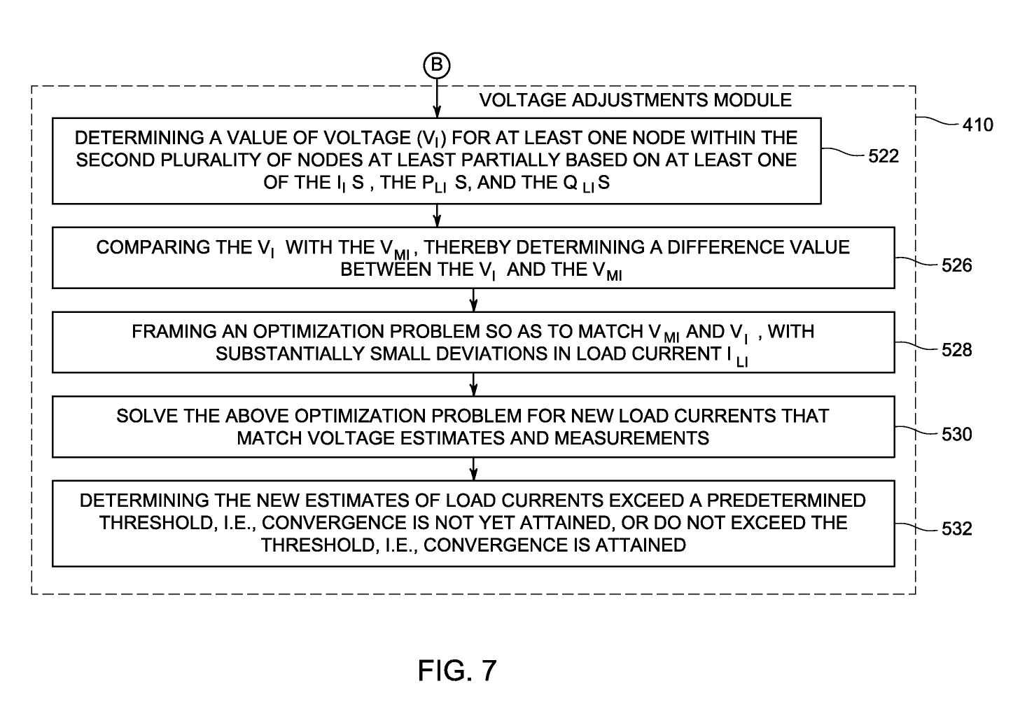

FIG. 5 is a detailed flow chart of method 500 for determining a distribution state estimation of the portion of electric power distribution system 300 (shown in FIG. 3) for which DSE system 200 (shown in FIG. 2) and process 400 (shown in FIG. 4) is used. FIG. 6 is a continuation of the flow chart shown in FIG. 5, and FIG. 7 is a continuation of the flow chart shown in FIG. 6. Referring to FIGS. 3, 4, 5, 6, and 7, in the exemplary embodiment, method steps 502 and 504 correspond to system data measurement and load estimate module 402 (only shown in FIG. 4).

Method 500 includes measuring 502 a first measured value of electric current transmission (I_{Mk}) between first plurality of nodes 350 (shown in FIG. 3), where, as above, k represents a particular segment. In the exemplary embodiment, real-time measurements of transmission of electric currents through the segments and the voltages of the associated nodes are recorded in real-time. I_{M1-2} and V_{M1} are recorded using first CT 336 and first PT 332, respectively. In alternative embodiments, any number of CTs, PTs, nodes, and segments are associated with the first portion of nodes that enables operation of DSE system 200 as described herein. First PT 332 records one of, or both of magnitudes and phase angles of real-time voltage measurements.

In some embodiments, in contrast to direct measurements of current flows I_{M}s through installed current transducers, measured currents I_{M}s are derived from real power flow measurement (P_{M}) devices and reactive power flow measurement (Q_{M}) devices. Therefore, direct determinations of electric current through segment 318 (shown in FIG. 3) are made from one of, or both of, real power flow measurements and reactive power flow measurements, i.e., I_{M} may be indirectly determined from measured power flows using the latest voltage estimations Vᵢ at the associated nodes. Further, in alternative embodiments, any number of CTs, PTs, P_{M} devices, Q_{M} devices, nodes, and segments are associated with first plurality of nodes 350 and second plurality of nodes 360 that enables operation of DSE system 200 as described herein.

For those embodiments, such as the exemplary embodiment, that record real-time measurements of I_{M} within segment 318, and do not have real and reactive power flow measurement instrumentation, method 500 also includes determining 504 at least one of real power flow (P_{Dk}) and reactive power flow (Q_{Dk}) between at least two first nodes within first plurality of nodes 350. In the exemplary embodiment, real-time indirect determinations of P_{Dk} and Q_{Dk} are derivations for segment 318 using real-time I_{M1-2} and V_{M1}, i.e., values for P_{D1-2} and Q_{D1-2} are derived. Also, alternatively, P_{DK}s and/or Q_{Dk}s are directly determined, i.e., measured in real-time through installed instrumentation, and may be referred to P_{Mk}s and/or Q_{Mk}s. However, as used herein, P_{Dk} and Q_{Dk} refer to real and reactive power flow values whether indirectly derived or directly measured. Further, alternatively, for those node and segment configurations that include a plurality of segments, real-time determinations of P_{Dk} and Q_{Dk} through measurements may be made in different segments, e.g., and without limitation, the P_{Dk} measurements may be taken in a first segment between a first pair of nodes and the Q_{Dk} measurements may be taken in a second segment between a second pair of nodes that may, or may not, be adjacent to the first segment and the first pair of nodes.

In the exemplary embodiment, method steps 506, 508, 510, 512, and 514 correspond to forward, backward sweep module 404 (shown in FIG. 4). Method 500 further includes determining 506, for second plurality of nodes 360 (shown in FIG. 3) positioned downstream of plurality of nodes 350, at least one of at least one estimated real power load value (PO and at least one estimated reactive power load value (Q_{Li}). As above, the “i” refers to the i^{th} node. In addition, a plurality of estimated load current values (I_{Li}s) based on the at least one of the at least one P_{Li} and the at least one Q_{Li} are determined 508 for second plurality of nodes 360. In some embodiments, use of installed current measurement instrumentation, e.g., second CT 338 in segment 320, is used to record real-time current flows.

Moreover, a determined value of voltage (Vᵢ) for at least one node within first plurality of nodes 350 is determined 510 as a function of at least one of directly measured and indirectly derived values of the P_{Dk}s, Q_{Dk}s, and I_{Mk}s described above. As above, the “i” refers to the i^{th} node. For example, such a voltage V₂ is determined for second node 304. Furthermore, a value of voltage (Vᵢ) for at least one node within second plurality of nodes 360 is determined 512 as a function of at least one of the P_{Li}, Q_{Li}, and I_{Li}s. Alternatively, in some embodiments, use of installed voltage measurement instrumentation, e.g., second PT 334 in fifth node 310, is used to record real-time voltages. Second PT 334 records one of, or both of magnitudes and phase angles of real-time voltage measurements.

As described above, for clarity, the use of predetermined input values for determining Vᵢs for first plurality of nodes 350 and second plurality of nodes 360, i.e., method steps 510 and 512 are clearly characterized and distinguished from each other. However, in alternative embodiments, some combinations of the input values for method steps 506, 508, 510, and 512 are used, e.g., without limitation, installed current, real power, and reactive power measurement instrumentation may be present in second plurality of nodes 360 to provide real-time determinations of P_{Dk}s and/or Q_{Dk}s in first plurality of nodes 350. Also, e.g., and without limitation, estimated load current values I_{Li}s based on P_{Li}s and Q_{Li}s are determined in portions of first plurality of nodes 350.

As a result of a combination of method steps 506, 508, 510, and 512, as well as using any other real-time measurement date, e.g., without limitation, I_{M2-3} and V_{M5}, a first set of estimated load currents is generated. Estimated third load current I_{L3} transmitted from third node 306, estimated fourth load current I_{L4} transmitted from fourth node 308, estimated sixth load current I_{L6} transmitted from sixth node 312, estimated seventh load current I_{L7} transmitted from seventh node 314, and estimated eighth load current I_{L8} transmitted from eighth node 316 are determined as described above. As such, a forward sweep followed by a backward sweep are executed to determine a first set of voltages and load currents for the nodes and segments in second plurality of nodes 360. For those embodiments of portion 301 that includes first plurality of nodes 350 without direct measurement instrumentations, those method steps associated with forward, backward sweep module 404 may also be applied to determine estimated line electricity transmission, of flows, i.e., current flows, real power flows, and reactive power flows, as well as the associated node voltages.

The plurality of I_{Li}s are summed 514 to determine summations of the plurality of I_{Li}s (ΣI_{Li}) in second plurality of nodes 360. For example, and without limitation, I_{L6} and I_{L7} are summed to generate a first ΣI_{Li} that approximates load current in segment 326. Similarly, I_{L3} and I_{L8} are summed to generate a second ΣI_{Li} that approximates I_{M2-3}. Also, I_{L4} is summed with the load current in segment 326 and I_{M2-3} to generate a third ΣI_{Li} that should approximate I_{M1-2}.

In the exemplary embodiment, method steps 516 and 518 correspond to DSE convergence module 406 (shown in FIG. 4). The load current summations ΣI_{Li}s are compared 516 with the immediately upstream I_{Mk}. For example, and without limitation, second ΣI_{Li}, is compared to I_{M2-3} and a first difference between the two is generated. Another iteration of forward, backward sweep module 404 and DSE convergence module 406 including method steps 506 through 516 to generate a second difference between second ΣI_{Li} and I_{M2-3}. Then, the difference value between the ΣI_{Li} and the I_{Mk} is determined 518 to exceed, or not exceed, a predetermined threshold value that is a function of a predetermined baseline value. Specifically, the second difference is compared to the first difference and if the variance between the two difference values is less than 1*10⁻⁴ of a baseline value, the second ΣI_{Li} is considered to be converged. For example, and without limitation, for a baseline value of I_{M2-3} of 10 amperes, if the first of two estimations of ΣI_{Li} is 10 amperes and the second of the two estimations of ΣI_{Li} falls between 9.9999 amperes and 10.0001 amperes, the current associated with second ΣI_{Li} and I_{M2-3} is considered converged. If this requirement is not met, the process continues iteratively until convergence is attained.

While the above example used current values, i.e., load currents L_{Li}s, determined currents I_{D}s, and measured currents I_{M}s, real power flow, reactive power flow, and voltages (described further below) may also be used in lieu of, or in conjunction with, currents, in any combination that enables DSE system 200 as described herein. Also, in the exemplary embodiment, all load current determinations executed for second plurality of nodes 360 substantially simultaneously.

In the exemplary embodiment, method step 520 corresponds to current adjustments module 408. If convergence of the load currents as described above is not attained, one, or both, of the P_{Li}s and the Q_{Li}s associated with that portion of second plurality of nodes 360 is adjusted 520 to facilitate substantially equalizing the ΣI_{Li} with the I_{Mk} such that convergence is attained. More than one iteration may be necessary and KCL equation (1) is adhered to in each iteration.

In the exemplary embodiment, method steps 522 through 532 correspond to voltage adjustments module 414. The method steps associated with voltage adjustments module 414 are performed after the method steps associated with current adjustments module 408. A value of determined voltage (Vᵢ) for at least one node within second plurality of nodes 360 is determined 522 at least partially based on at least one of the previous determinations of the L_{Li}s, the P_{Li}s, and the Q_{Li}s made within second plurality of nodes 360. For each Vᵢ determined above, Vᵢ is compared 526 with a corresponding V_{Mi}, if it exists, thereby determining a difference value between the Vᵢ and the V_{Mi}. In the exemplary embodiment, a difference value between each node with a voltage estimation Vᵢ and a corresponding V_{Mi} is generated substantially simultaneously, thereby accelerating the iterative process to attain convergence. Alternatively, the difference values are determined is a predetermined sequence.

The primary goal of method 500 is to generate a plurality of Vᵢs for as many nodes being evaluated throughout portion 301, where the difference between successive iterations decreases until a predetermined differential value between two successive iterations is achieved, i.e., the variance between two successive difference values is less than 1*10⁻⁴ of a predetermined baseline value, e.g., and without limitation, 110 volts, 220 volts, and 440 volts for the associated node voltages without violating KCL (equation (1)) and KVL (equation (2)). Therefore, an optimization problem, i.e., an optimization algorithm (J) is framed 528 so as to match V_{Mi} and Vᵢ, with deviations in associated iterative determinations of load currents (I_{Li}s). As used herein, the terms “frame the algorithm” and related terms refers to setting up an algorithm with the necessary variables, parameters, and constraints prior to solving. Also, as used herein, the terms “optimization” and “minimize”, and similar terms, are used to refer to driving method 500 to attain a decrease of the variance between two successive difference values of node voltages to less than 1*10⁻⁴ of the predetermined value for the associated node voltages.

As such, in the exemplary embodiment of process 400, and method steps 522 through 532, DSE convergence is considered to be achieved when a voltage difference between two successive iterations at all nodes 302 through 316 is determined to be less than 0.01 percent, i.e., 0.0001, or 1*10⁻⁴ of a predetermined base value. For example, and without limitation, if the first of two estimations of voltage is 110 volts, and if the second voltage estimate is between 109.9999 volts and 110.0001 volts, voltage for that particular node is considered converged. Alternatively, any value to define convergence may be used that enables operation of process 400 and method 500 as described herein. Also, alternatively, any other convergence criteria that enables operation of process 400 and method 500 as described herein may also be used.

In the exemplary embodiment, the optimization algorithm is formulated such that a weighted sum of squares of magnitudes of additional changes in load current, required to match voltage measurements and estimates, is expressed by the relationship:

minimize J=Σwᵢ(ΔI_{Li}^{re}^{²}+ΔI_{Li}^{im}^{²}) (4)

where ΔI_{Li}=ΔI_{Li}^{re}+jΔI_{Li}^{im}, (5)

and where i is an element of the set of load buses, or nodes N, wᵢ is the weight for the i^{th} node, ΔI_{Li} represents the additional load current adjustments at the i^{th} node to match voltage measurements, and ΔI_{Li}^{re} and jΔI_{Li}^{im} represent the real and imaginary components, respectively, of ΔI_{Li}. This optimization problem is subject to two constraints. The first constraint is that ΣI_{Li}=I_{Mk} should not be violated while matching voltage measurements. For each measured current and derived current from real and reactive power flow measurements, the sum of the downstream additional load current adjustments (to match the voltage measurements) should be zero, so that the current determinations continue to be matched. A series of equations are set up as follows:

Σ₁ΔI_{Li}=Σ₁ΔI_{Li}^{re}+jΣ₁ΔI_{Li}^{im}=0, (6-1)

Σ₂ΔI_{Li}=Σ₂ΔI_{Li}^{re}jΣ₂ΔI_{Li}^{im}=0, (6-2)

ΣₚΔI_{Li}=ΣₚΔI_{Li}^{re}+jΣₚΔI_{Li}^{im}=0, (6-p)

where p corresponds to the number of current measurements in portion 301 of distribution system 300, m corresponds to the numbers of the buses, or nodes that are used for matching the current measurements in DSE current stage 401 (shown in FIG. 4).

Separating the real and imaginary quantities provides the following p pairs of equations, i.e., 2*p equations corresponding to p current measurements as described above:

Σ₁ΔI_{Li}^{re}=0 & Σ1ΔI_{Li}^{im}=0, (7-1)

Σ₂ΔI_{Li}^{re}=0 & Σ2ΔI_{Li}^{im}=0, (7-2)

ΣₚΔI_{Li}^{re}=0 & ΣpΔI_{Li}^{im}=0, (7-p)

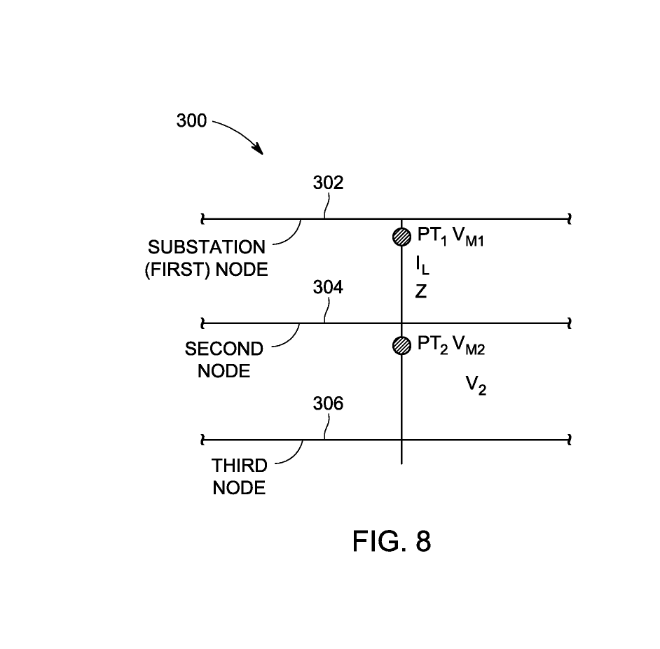

FIG. 8 is a schematic view of a portion of electric power distribution system 300 for describing a voltage matching constraint. The second constraint is associated with matching the voltage determinations. Voltage determinations are matched by changing a voltage drop between two adjacent measurements. FIG. 8 shows a first potential transformer PT₁ that generates a first, or upstream real-time voltage measurement V_{M1}. FIG. 8 also shows a second potential transformer PT₂ that generates a second, or downstream real-time voltage measurement V_{M2}. Upstream voltage measurement V_{M1} is considered as the reference measurement for this discussion. The change in voltage drop is represented by ΣΔI_{Lk}*Zₖ, where ΔI_{Li} is the change in line segment current of the k^{th} line segment and Zₖ is the impedance associated with the respective k^{th} line segment, e.g., without limitation, segment 318 between first node 302 and second node 304. ΣΔI_{Lk}*Zₖ is adjusted by a value (Vₑ), which is the phasor difference of measured downstream voltage V_{M2} and a voltage calculated (V₂) after matching current, real, and reactive power flow measurements in DSE current stage 401. In equation form, this relationship is shown as:

ΣΔI_{Li}*Zₖ=V_{M2}−V₂=Vₑ, (8)

where k belongs to a set of line segments between V_{M1} and V_{M2}

Each measured voltage magnitude is converted into a complex quantity by leveraging the latest calculated angle information of the node where the measurement is taken if the voltage angle information is not measured at the same location. If the voltage angle is measured at the same location, the same angle information of the node where the measurement is taken is leveraged to convert into a complex quantity. The change in voltage drop between two adjacent voltage measurements is adjusted by changing load currents (I_{Li}s). The load currents that need to be changed depend on the locations of the loads and their contribution to the drop in the segment. As described above, the 2*p equations (7-1) through (7-p) facilitate not violating matched current, real power, and reactive power flows while load currents are adjusted to match the voltage determinations. Therefore, the changes to the load currents are strictly limited to small values.

A set of voltage drop change equations for q voltage measurements after re-arranging and generalizing equation (8) are as follows, where Zₛᵢ is a sum of the impedances of the segments (or branches, or lines) on which load current (I_{Li}) flows between adjacent voltage measurements. A Zₛᵢ corresponding to an I_{Li} could be different for adjacent voltage measurements. The resulting equations are:

Σ_{q-1}ΔI_{Li}Zₛᵢ=V_{e(q-1)}=V_{M(q-1)}−V_{(q-1)}, (9)

where V_{e (q-1)} correspond to the differences of voltage measurements and voltage estimates at the (q−1)^{th} voltage measurement location after the activities in DSE current stage 401 (shown in FIG. 4). The source bus is used as a reference, Therefore, there are q−1 downstream nodes to evaluate. After substitution for ΔI_{Li}, Zₛᵢ, and Vₑᵢ with the following:

ΔI_{Li}=ΔI_{Li}^{re}+jΔI_{Li}^{im}, (10)

Zₛᵢ=Zₛᵢ^{re}+jZₛᵢ^{im}, and (11)

Vₑ=Vₑ^{re}+jVₑ^{im}. (12)

and re-arranging the above equation (9) will lead to the following equation with the complex quantities expanded into real and imaginary components:

Σ_{q-1}(ΔI_{Li}^{re}Zₛᵢ^{re}−ΔI_{Li}^{im}Zₛᵢ^{im})+j(ΔI_{Li}^{re}Zₛᵢ^{im}+ΔI_{Li}^{im}Zₛᵢ^{re})=V_{e(q-1)}^{re}+jV_{e(q-1)}^{re}. (13)

In the above equations 13, real and imaginary components are equated to produce 2*(q−1) sets of equations corresponding to q voltage measurements, given that source bus is taken as reference.

Once the algorithms and their constraints are framed, the above optimization problem J for new load currents that match the voltage estimates and measurements is solved 530. In the exemplary embodiment, the problem is solved for using classical Lagrangian techniques to minimize J. Alternatively, any mathematical process that enables performance of method step 530 as described herein is used. As per the Lagrangian technique, the modified objective function is given by:

J′=0.5Σwᵢ(ΔI_{Li}^{re}^{²}+Δ_{Li}^{im}^{²})+λ₁ΣₐΔI_{Lm}^{re}+λ₂ΣₐΔI_{Lm}^{im}+ . . . + λ₍₂ₚ₋₁₎ΣₚΔI_{Lm}^{re}+λ₂ₚΣₚΔI_{Lm}^{im}+λ₍₂ₚ₊₁₎{Σ_{b}(ΔI_{Li}^{re}Zₛᵢ^{re}−ΔI_{Li}^{im}Zₛᵢ^{im})−Vₑ₁^{re}}+λ₍₂ₚ₊₂₎{E_{b}(ΔI_{Lm}^{re}Zₛᵢ^{im}+ΔI_{Li}^{im}Zₛᵢ^{re})−Vₑ₁^{im}}+ . . . + λ_{(2p+2q-3)}{Σ_{q-1}(ΔI_{Li}^{re}Zₛᵢ^{re}−ΔI_{Li}^{im}Zₛᵢ^{im})−V_{e(q-1)}^{re}}+λ_{(2p+2(q-1)}{Σ_{q-1}(ΔI_{Li}^{re}Zₛᵢ^{im}+ΔI_{Li}^{im}Zₛᵢ^{re})−V_{e(q-1)}^{im}}, (14)

where the lambdas (λs) are Lagrangian coefficients. A solution of the minimization equation (14) is obtained by taking the partial derivative of equation (14) with respect to each of the ΔI_{Li}^{re}, ΔI_{Li}^{im}, λ₁, . . . , λ_{2p+2q} and set it equal to zero.

The result of these mathematical operations yields values for λᵢ that are used to compute a set of values for ΔI_{Li}^{re} and ΔI_{Li}^{im} which can match the voltage measurements. The solution depends on measurements used for DSE process 400 (shown in FIG. 4) and system 300 topology. Therefore, the solution is calculated whenever there is a change in the measurement set used by DSE system 300. Recalculation of the solution is also required for any change in the topology of system 300.

After ΔI_{Li} is determined, ΔI_{Li}^{ch} is calculated. The load current adjustments are converted into real and reactive power flow adjustments, thereby leveraging the latest voltage determinations Vᵢ and adjusting the values of loads P_{Li}s and Q_{Li}s to determine adjustments to the L_{Li}s. This process is continued, or iterated until the voltages converge as described above.

As an example, and referring to portion 301 in FIG. 3, DSE system 200 in FIG. 2, process 400 in FIG. 4, and method 500 in FIGS. 5 through 7, a convergence of voltage determinations are generated as follows. Initially, current, real power, and reactive power flow measurement convergence is iteratively performed using DSE current stage 401 and method steps 502 through 520. By this point in method 500, the current, real power, and reactive power flow measurements I_{M1-2} and I_{M2-3} are matched with that of corresponding estimated values such that I_{L3}+I_{L8} substantially matches I_{M2-3} and I_{L3}+I_{L8}+I_{L4}+I_{L6}+I_{L7} substantially matches I_{M1-2}. Also, each of nodes 302 through 330 has a computed (or measured) voltage. However, it is observed by DSE system 200 that the voltage estimates and the voltage measurements do not match. DSE voltage stage 412 and method steps 522 through 530 are used to match voltage measurements, i.e., V_{M1} and V_{M5}, and the computer-generated voltage determinations with changes in the load currents I_{Li}s, i.e., ΔI_{Li}s. The equation for second plurality of nodes is as follows:

J=w₃(ΔI_{L3}^{re}^{²}+ΔI_{L3}^{im}^{²})+w₄(ΔI_{L4}^{re}^{²}+ΔI_{L4}^{im}^{²})+w₆(ΔI_{L6}^{re}^{²}+ΔI_{L6}^{im}^{²})+w₇(ΔI_{L7}^{re}^{²}+ΔI_{L7}^{im}^{²})+w₈(ΔI_{L8}^{re}^{²}+ΔI_{L8}^{im}^{²}). (15)

Subjecting equation (15) to the constraints defined by KCL equation (1) provides:

I_{L3}+ΔI_{L3}+I_{L8}+ΔI_{L8}=I_{M2-3}, and (16)

ΔI_{L8}+ΔI_{L3}=0, (17)

where I_{M2-3} and I_{L3} plus I_{L8} are matched, since the estimated changes in the load current for the loads associated with third node 306 and eight node 316 sum to zero. Also, using the expression:

ΔI_{L4}+ΔI_{L6}+ΔI_{L7}=0, (18)

where the estimated changes in load current for the loads associated with fourth node 308, sixth node 312, and seventh node 314 sum to zero, and in conjunction with equation (16), I_{M1-2} and I_{L4}, I_{L6}, and I_{L7}, and I_{L8} and I_{L3} (I_{M2-3}) are matched.

The voltage drop between V_{M1} and V_{M5} now needs to be adjusted to match V_{M5}. Using equation (2) for KVL provides:

ΔI_{L3}*Zₛ₃+ΔI_{L8}*Zₛ₈+ΔI_{L4}*Zₛ₄+ΔI_{L6}*Zₛ₆+ΔI_{L7}*Zₛ₇=Vₑ, (19)

where ΔI_{Li} is the change in current at the i^{th} node, Vₑ= V̅_̅{̅M̅5̅}̅− V̅₅̅, and where V₅ is a calculated voltage at fifth node 310. As the phase angle information at fifth node 310 is not available from direct measurement, the phase angle of the calculated voltage on fifth node 310 is used to convert V_{M5} into a complex quantity. Zₛᵢ is a sum of the impedances of the segments (or branches, or lines) of the i^{th} node on which load current (I_{Li}) flows between adjacent voltage measurements. The impedances Zₛᵢ may be different for every KVL analysis. In the exemplary embodiment, for fifth node 310, the impedances Zₛᵢ, are determined using the following equations:

V₅=V_{M1}−TVD₅, (20)

TVD₅=ΔV₁₋₂+ΔV₂₋₄+ΔV₄₋₅, (21)

where TVD₅=the total voltage drop to estimate the voltage at the measurement location, i.e., fifth node 310, ΔV₁₋₂ is the voltage drop along segment 318 between first node 302 and second node 304, ΔV₂₋₄ is the voltage drop along segment 324 between second node 304 and fourth node 308, and ΔV₄₋₅ is the voltage drop along segment 326 between fourth node 308 and fifth node 310. The voltage drops are expressed as:

ΔV₁₋₂=Z₁₋₂*(I_{L3}+I_{L8}+I_{L4}+I_{L6}+I_{L7}), (22)

ΔV₂₋₄=Z₂₋₄*(I_{L4}+I_{L6}+I_{L7}), and (23)

ΔV₄₋₅=Z₄₋₅*(I_{L6}+I_{L7}). (24)

Substituting the voltage drops of equations (21) through (23) into equation (20):

TVD₅=Z₁₋₂*(I_{L3}+I_{L8}+I_{L4}+I_{L6}+I_{L7})+Z₂₋₄*(I_{L4}+I_{L6}+I_{L7})+Z₄₋₅*(I_{L6}+I_{L7}). (25)

Rearranging equation (24) as follows to match the load currents I_{Li}s with the sum of the impedances Z provides:

TVD₅=I_{L3}(Z₁₋₂)+I_{L8}(Z₁₋₂)+I_{L4}(Z₁₋₂+Z₂₋₄)+I_{L6}(Z₁₋₂+Z₂₋₄+Z₄₋₅)+I_{L7}(Z₁₋₂+Z₂₋₄+Z₄₋₅), (26)

such that:

Zₛ₃=Z₁₋₂, (27)

Zₛ₈=Z₁₋₂, (28)

Zₛ₄=Z₁₋₂+Z₂₋₄, (29)

Zₛ₆=Z₁₋₂+Z₂₋₄+Z₄₋₅, and (30)

Zₛ₇=Z₁₋₂+Z₂₋₄+Z₄₋₅. (31)

Considering equal weights (wᵢ=1) for all loads, taking the partial derivative of equation (15) with respect to each of the ΔI_{Li}^{re}, ΔI_{Li}^{im}, λ₁, . . . , λ_{2p+2q} and setting it equal to zero, solving for the lambdas (λ), and then computing ΔI_{Li} for each load. The ΔI_{Li}'s for all the nodal loads are as follows:

ΔL₃^{re}=−(λ₁+λ₅*Zs₃^{re}+λ₆*Zs₃^{im}), (32)

ΔL₃^{im}=−(λ₂−λ₅*Zs₃^{im}+λ₆*Zs₃^{re}), (33)

ΔL₈^{re}=−(λ₁+λ₅*Zs₈^{im}+λ₆*Zs₈^{im}), (34)

ΔL₈^{im}=−(λ₂−λ₅*Zs₈^{im}+λ₆*Zs₈^{im}), (35)

ΔL₄^{re}=(λ₃+λ₅*Zs₈^{im}+λ₆*Zs₄^{im}), (36)

ΔL₄^{im}=−(λ₄−λ₅*Zs₄^{im}+λ₆*Zs₄^{re}), (37)

ΔL₆^{re}=−(λ₃+λ₅*Zs₆^{re}+λ₆*Zs₆^{im}), (38)

ΔL₆^{im}=−(λ₄−λ₅*Zs₆^{im}+λ₆*Zs₆^{re}), (39)

ΔL₇^{re}=−(λ₃+λ₅*Zs₇^{re}+λ₆*Zs₇^{im}, and (40)

ΔL₇^{im}=−(λ₄−λ₅*Zs₇^{im}+λ₆*Zs₇^{re}). (41)

Therefore, the new estimates of load currents are determined 532 and if they exceed a predetermined threshold, convergence is not yet attained, or if they do not exceed the threshold, convergence is attained. The process is iterated until the ΔI_{Li}'s for all the nodal loads attain DSE convergence as described herein. Throughout the iterations, the most recent voltage estimation for each node is used to determine the associated current flow therethrough.

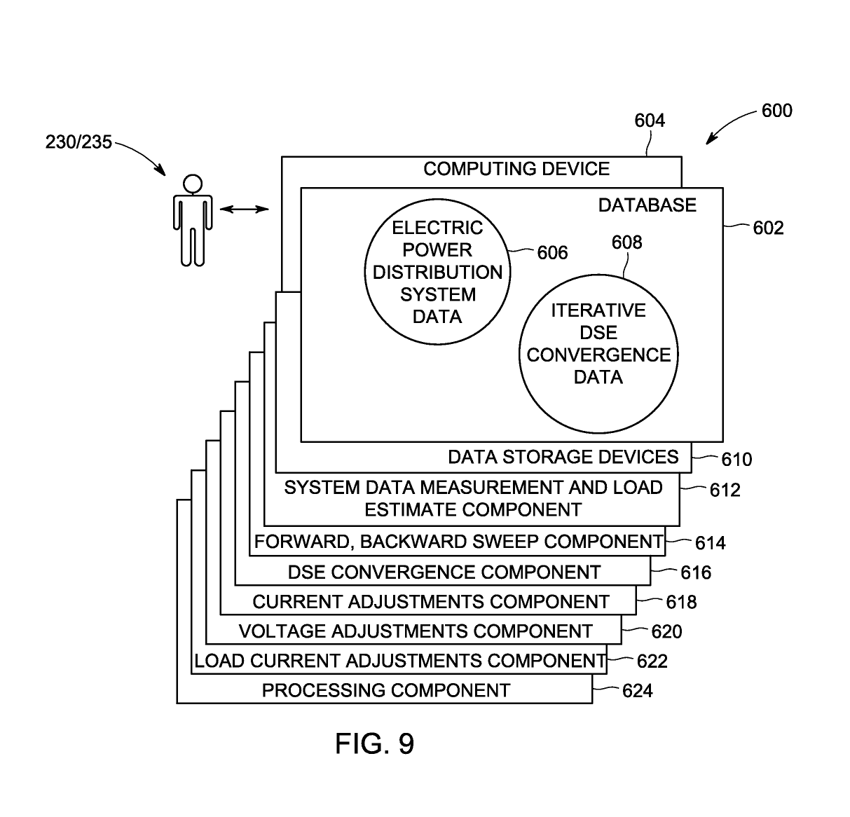

FIG. 9 is an exemplary configuration 600 of a database 602 within a computing device 604, along with other related computing components, that may be used during determining a distribution state estimation as described herein. Database 602 is coupled to several separate components within computing device 604, which perform specific tasks. In the example embodiment, computing device 604 may be computing device 105 (shown in FIGS. 1 and 2).

In the example embodiment, database 602 includes electric power distribution system data 606 and iterative convergence data 608. Electric power distribution system data 606 includes information such as topology configuration information and monitoring sensor information (shown in FIG. 3), i.e., measured voltage and current magnitudes and phase angles, real power flow, and reactive power flow. Iterative convergence data 608 includes information associated with iterations of current and voltages computed during practice of process 400 through method 500 as described in reference to FIGS. 4 and 5, respectively.

Computing device 604 includes the database 602, as well as data storage devices 610. Computing device 604 also includes a system data measurement and load estimate component 612 for executing method steps 502 and 504 (shown in FIG. 5), including receiving electric power distribution system data 606. Computing device 604 also includes a forward, backward sweep component 614 for executing method steps 506 through 514 (shown in FIGS. 5 and 6). Computing device 604 further includes a DSE convergence component 616 for executing method steps 516 and 518 (shown in FIG. 6). Computing device 604 also includes a current adjustments component 618 for executing method step 520 (shown in FIG. 7) and generating ΔI_{Li}′ signals 410 (shown in FIG. 4). Computing device 604 further includes a voltage adjustments component 620 for executing method steps 522 through 532 (shown in FIG. 7) and generating ΔI_{Li} signals 416 (shown in FIG. 4). Computing device 604 also includes a load current adjustments component 622 that receives ΔI_{Li}′ signals 410 and ΔI_{Li} signals 416, sums them, and generates ΔLᵢ^{ch} signals 420. A processing component 624 assists with execution of computer-executable instructions associated with the distribution state estimation (DSE) system 200. Components 614, 616, 618, 620, and 622 use and generate iterative DSE convergence data 608.

The above-described distribution state estimation (DSE) system for the electric power distribution systems provide a cost-effective method for facilitating the quality of voltage on segments of the distribution systems that do not have hardware monitoring devices for real-time voltage measurements. Specifically, the embodiments described herein extend the functionality of known DSEs to estimate voltages throughout the distribution system with a significant improvement in accuracy in real-time. More specifically, the embodiments described herein extend the functionality of known DSEs from merely converging with respect to current flows throughout the distribution system to converging with respect to node voltages. The resultant high-confidence estimated voltage values facilitate operation of voltage control applications such as, without limitation, integrated volt/VAR control (IVVC), coordinated volt/VAR control (CVVC), and conservation voltage reduction (CVR).

An exemplary technical effect of the methods, systems, and apparatus described herein includes at least one of: (a) substantially increasing the accuracy of voltage estimations throughout an electric power distribution system; and (b) determining voltage estimations throughout an electric power distribution system in an iterative process where the differences between voltages and currents estimated for a segment of the distribution system converge toward a predetermined value between two successive estimations.

Exemplary embodiments of distribution state estimation (DSE) system for estimating voltages on electric power distribution systems, and methods of operating such systems are not limited to the specific embodiments described herein, but rather, components of systems and/or steps of the methods may be utilized independently and separately from other components and/or steps described herein. For example, the methods may also be used in combination with other systems requiring estimated voltages, and are not limited to practice with only the electric power distribution systems and methods as described herein. Rather, the exemplary embodiment can be implemented and utilized in connection with many other transmission applications that are currently configured to transmit and receive electric power.

Although specific features of various embodiments of the invention may be shown in some drawings and not in others, this is for convenience only. In accordance with the principles of the invention, any feature of a drawing may be referenced and/or claimed in combination with any feature of any other drawing.

Some embodiments involve the use of one or more electronic or computing devices. Such devices typically include a processor or controller, such as a general purpose central processing unit (CPU), a graphics processing unit (GPU), a microcontroller, a reduced instruction set computer (RISC) processor, an application specific integrated circuit (ASIC), a programmable logic circuit (PLC), and/or any other circuit or processor capable of executing the functions described herein. The methods described herein may be encoded as executable instructions embodied in a computer readable medium, including, without limitation, a storage device and/or a memory device. Such instructions, when executed by a processor, cause the processor to perform at least a portion of the methods described herein. The above examples are exemplary only, and thus are not intended to limit in any way the definition and/or meaning of the term processor.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal language of the claims.

What is claimed is:

1. A computer-based method of estimating a state of an electric power distribution system using a computer device including at least one processor, the electric power distribution system including a plurality of nodes positioned therein and at least one electrical monitoring sensor positioned therein, at least one said method comprising:
measuring at least one of electric current flow (I), real power flow (P), and reactive power flow (Q) and receiving a value of the at least one of I, P, and Q by the computing device;
determining, by the processor, at least one of:
at least one estimated real power load value (P_{Li}); and
at least one estimated reactive power load value (Q_{Li});
determining, by the processor, a plurality of estimated load current values (I_{Li}s) based on the at least one of the at least one P_{Li} and the at least one Q_{Li};
measuring a value of voltage (V_{M}) for at least one node within the plurality of nodes and receiving the value of the V_{M} by the computing device;
determining, by the processor, a voltage estimate (Vᵢ) for the at least one node within the plurality of nodes;
comparing, by the processor, the Vᵢ with the V_{M}, thereby determining a difference value between the Vᵢ and the V_{M};
determining, by the processor, that the difference value exceeds a predetermined threshold; and
adjusting, by the processor, the at least one of the at least one P_{Li} and the at least one Q_{Li} to facilitate substantially equalizing the Vᵢ with the V_{M}.

2. The method in accordance with claim 1 further comprising generating, by the processor, at least one value of measured electric current flow (I_{M}) through at least one of:
the measured value of I through a current measurement device; and
a derived value of I through at least one of:
the measured value of real power flow (P_{M}) through a real power flow measurement device; and
the measured value of reactive power flow (Q_{M}) through a reactive power flow measurement device.

3. The method in accordance with claim 2 further comprising:
summing, by the processor, the plurality of I_{Li}s, thereby determining, by the processor, a summation of the plurality of I_{Li}s (ΣI_{Li});
comparing, by the processor, the corresponding ΣI_{Li} with the corresponding I_{M}, thereby determining, by the processor, a difference value between the ΣI_{Li} and the corresponding at least one I_{M};
determining, by the processor, the difference value between the ΣI_{Li} and the at least one I_{M} exceeds a predetermined threshold; and
adjusting, by the processor, the at least one of the at least one P_{Li} and the at least one Q_{Li} to facilitate substantially equalizing the ΣI_{Li} with the at least one I_{M}.

4. The method in accordance with claim 1, wherein determining, by the processor, a voltage estimate (Vᵢ) comprises determining, by the processor, a value of voltage (Vᵢ) as a function of at least one of the P_{Li}s, the Q_{Li}s, and the I_{Li}s.

5. The method in accordance with claim 2, wherein determining, by the processor, a voltage estimate (Vᵢ) for the at least one node comprises at least one of:
adjusting, by the processor, the at least one P_{Li} to approach one of the measured value of P_{M} and a derived value of P_{M} generated, by the processor, from the measured value of I_{M};
adjusting, by the processor, the at least one Q_{Li} to approach one of the measured value of Q_{M} and a derived value of Q_{M} generated, by the processor, from the measured value of I_{M}; and
adjusting, by the processor, the at least one I_{Li} to approach one of the measured value of I_{M} and a derived value of I_{M} generated, by the processor, from the at least one of the measured values of P_{M} and Q_{M}.

6. The method in accordance with claim 1, wherein:
measuring the V_{M} comprises at least one of measuring a voltage magnitude and a voltage phase angle through a voltage measurement device; and
determining the Vᵢ comprises determining, by the processor, at least one of a voltage magnitude and a voltage phase angle.

7. The method in accordance with claim 1, wherein determining, by the processor, a plurality of I_{Li}s comprises using, by the processor, the Vᵢ.

8. The method in accordance with claim 1, wherein adjusting, by the processor, the at least one of the at least one P_{Li} and the at least one Q_{Li} to facilitate substantially equalizing the Vᵢ with the V_{M} comprises converging estimated voltages and converging estimated currents substantially simultaneously.

9. A computer-based distribution state estimation (DSE) system for estimating a state of an electric power distribution system, the electric power distribution system including a plurality of nodes positioned therein, the electric power distribution system further including an integrated volt/VAR control (IVVC) system, said DSE system comprising:
at least one measurement device; and
at least one processor coupled to said at least one measurement device, said at least one processor configured to:
determine at least one of:
at least one estimated real power load value (P_{Li}); and
at least one estimated reactive power load value (Q_{Li});
determine a plurality of estimated load current values (I_{Li}s) based on the at least one of the at least one P_{Li} and the at least one Q_{Li};
determine a voltage estimate (Vᵢ) for at least one node in the plurality of nodes;
compare the Vᵢ with a measured value of voltage (V_{M}) for the at least one node within the plurality of nodes, thereby determine a difference value between the Vᵢ and the V_{M};
determine that the difference value exceeds a predetermined threshold; and
adjust the at least one of the at least one P_{Li} and the at least one Q_{Li} to facilitate substantially equalizing the Vᵢ with the V_{M}.

10. The DSE system in accordance with claim 9, wherein said at least one measurement device comprises at least one of a current measurement device, a real power flow measurement device, a reactive power flow measurement device, said at least one processor is further configured to generate at least one value of measured electric current flow (I_{M}) through at least one of:
a measured value of I through the current measurement device; and
a derived value of I through at least one of:
a measured value of real power flow (P_{M}) through the real power flow measurement device; and
a measured value of reactive power flow (Q_{M}) through the reactive power flow measurement device.

11. The DSE system in accordance with claim 10, wherein said at least one processor is further configured to:
sum the plurality of L_{Li}s, thereby determine a summation of the plurality of I_{Li}s (ΣI_{Li});
compare the corresponding ΣI_{Li} with the I_{M}, thereby determine a difference value between the corresponding ΣI_{Li} and the corresponding at least one I_{M};
determine the difference value between the ΣI_{Li} and the at least one I_{M} exceeds a predetermined threshold; and
adjust the at least one of the at least one P_{Li} and the at least one Q_{Li} to facilitate substantially equalize the ΣI_{Li} with the at least one I_{M}.

12. The DSE system in accordance with claim 9, wherein said processor is further configured to determine a value of voltage (Vᵢ) as a function of at least one of the P_{Li}s, the Q_{Li}s, and the I_{Li}s.

13. The DSE system in accordance with claim 10, wherein said processor is further configured to at least one of:
adjust the at least one P_{Li} to approach one of the measured value of P_{M} and a derived value of P_{M} generated from the measured value of I_{M}; and
adjust the at least one Q_{Li} to approach one of the measured value of Q_{M} and a derived value of Q_{M} generated from the measured value of I_{M}.
adjusting, by the processor, the at least one I_{Li} to approach one of the measured value of I_{M} and a derived value of I_{M} generated, by the processor, from the at least one of the measured values of P_{M} and Q_{M}.

14. The DSE system in accordance with claim 9, wherein said at least one measurement device is configured to measure at least one of a voltage magnitude and a voltage phase angle, and said processor is further configured to determine the Vᵢ by determining at least one of a voltage magnitude and a voltage phase angle.

15. The DSE system in accordance with claim 9, wherein said processor is further configured to determine the plurality of I_{Li}s using the Vᵢ.

16. The DSE system in accordance with claim 9, wherein said processor is further configured to converge estimated voltages and converge estimated currents substantially simultaneously.

17. One or more computer-readable storage media having computer-executable instructions embodied thereon, wherein when executed by at least one processor, the computer-executable instructions cause the at least one processor to:
determine at least one of:
at least one estimated real power load value (P_{Li}); and
at least one estimated reactive power load value (Q_{Li});
determine a plurality of estimated load current values (I_{Li}s) based on the at least one of the at least one P_{Li} and the at least one Q_{Li};
determine a voltage estimate (Vᵢ) for at least one node in the plurality of nodes;
compare the Vᵢ with a measured value of voltage (V_{M}) for the at least one node within the plurality of nodes, thereby determine a difference value between the Vᵢ and the V_{M};
determine that the difference value exceeds a predetermined threshold; and
adjust the at least one of the at least one P_{Li} and the at least one Q_{Li} to facilitate substantially equalizing the Vᵢ with the V_{M}.

18. The one or more computer-readable storage media having computer-executable instructions embodied thereon in accordance with claim 17, wherein when executed by at least one processor, the computer-executable instructions further cause the at least one processor to:
determine one of a measured value of I through a current measurement device, a measured value of real power flow through a real power flow measurement device, and a measured value of reactive power flow through a reactive power flow measurement device; and
generate at least one value of measured electric current flow (I_{M}) through at least one of:
the measured value of I through the current measurement device; and
a derived value of I through at least one of:
the measured value of real power flow (P_{M}); and
the measured value of reactive power flow (Q_{M}).

19. The one or more computer-readable storage media having computer-executable instructions embodied thereon in accordance with claim 18, wherein when executed by at least one processor, the computer-executable instructions further cause the at least one processor to:
sum the plurality of I_{Li}s, thereby determine a summation of the plurality of I_{Li}s (ΣI_{Li});
compare the corresponding ΣI_{Li} with the corresponding I_{M}, thereby determine a difference value between the ΣI_{Li} and the corresponding at least one I_{M};
determine the difference value between the ΣI_{Li} and the at least one I_{M} exceeds a predetermined threshold; and
adjust the at least one of the at least one P_{Li} and the at least one Q_{Li} to facilitate substantially equalize the ΣI_{Li} with the at least one I_{M}.

20. The one or more computer-readable storage media having computer-executable instructions embodied thereon in accordance with claim 17, wherein when executed by at least one processor, the computer-executable instructions further cause the at least one processor to converge estimated voltages and converge estimated currents substantially simultaneously.
